(19) United States
(12) Patent Application Publication
(10) Pub. No.: US 2012/0014081 A1
(43) Pub. Date: Jan. 19, 2012

(54) VOLTAGE ADJUSTING CIRCUIT, METHOD, AND MOTHERBOARD INCLUDING SAME

(75) Inventor: MING-YUAN HSU, Tu-Cheng (TW)

(73) Assignee: HON HAI PRECISION INDUSTRY CO., LTD., Tu-Cheng (TW)

(21) Appl. No.: 12/954,665

(22) Filed: Nov. 25, 2010

(30) Foreign Application Priority Data
Jul. 19, 2010 (TW) 99123702

(51) Int. Cl. H05K 7/06; H03L 5/00

(52) U.S. Cl. 361/807; 327/306

(57) ABSTRACT

A voltage adjusting circuit includes a voltage adjusting chip, a processor, first and second voltage converting circuits, and a control circuit. The voltage adjusting chip converts a first voltage to a second voltage. The processor receives the second voltage and a control signal. The second voltage converting circuit converts the second voltage to a third voltage. The first voltage converting circuit converts the third voltage to the second voltage according to the control signal from the processor for supplying the second voltage to the processor and the control circuit. The control circuit is connected between the first voltage converting circuit and the voltage adjusting chip. The control circuit deactivates the voltage adjusting chip when receiving the second voltage from the first voltage converting circuit.

### BACKGROUND

1. Technical Field

The present disclosure relates to a voltage adjusting circuit, a voltage adjusting method, and a motherboard including the voltage adjusting circuit.

2. Description of Related Art

When an electronic device is in a standby state, a processor monitors whether an external control is activated. At this time, a voltage adjusting chip converts a +19V voltage to a +3.3V voltage, for supplying power to the processor. If an external control is activated, the electronic device is restored. After, however, the voltage adjusting chip continues to supply voltage to the processor, resulting in an unnecessary expenditure of power.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a block diagram of an exemplary embodiment of a voltage adjusting circuit of a motherboard.

FIG. 2 is a flowchart of an exemplary embodiment of a voltage adjusting method of a motherboard of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

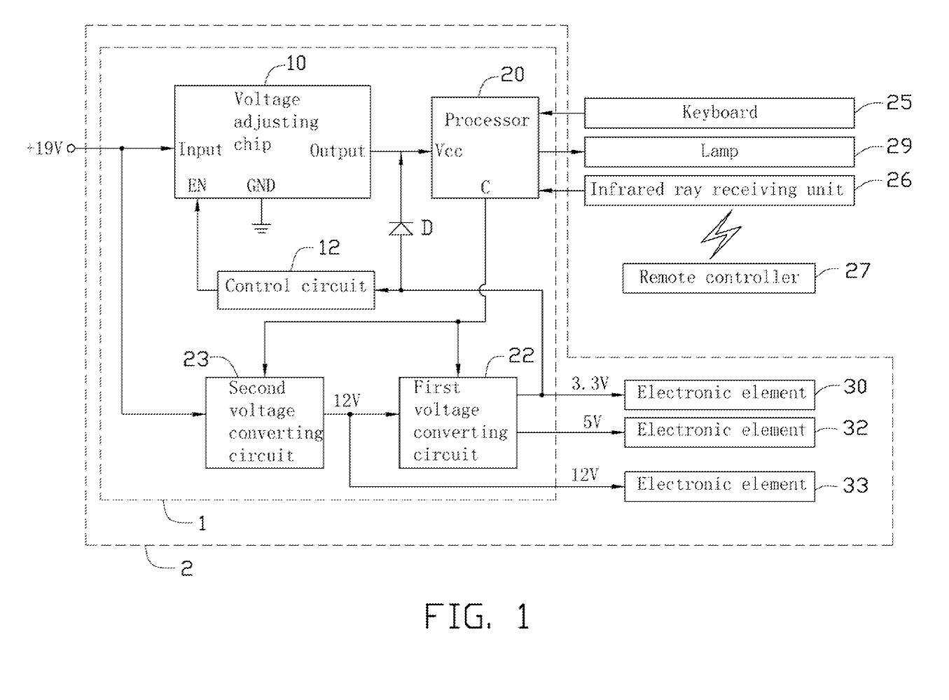

Referring to FIG. 1, an exemplary embodiment of a voltage adjusting circuit 1 is arranged on a motherboard 2. The voltage adjusting circuit 1 includes a voltage adjusting chip 10, a control circuit 12, a diode D, a processor 20, a first voltage converting circuit 22, and a second voltage converting circuit 23.

An input terminal of the voltage adjusting chip 10 receives a +19 volt (V) voltage. An output terminal of the voltage adjusting chip 10 is connected to a power terminal of the processor 20. The voltage adjusting chip 10 converts the +19V voltage to a +3.3V voltage for supplying the +3.3V voltage to the processor 20. An enable terminal of the voltage adjusting chip 10 is connected to an output terminal of the control circuit 12. An input terminal of the control circuit 12 is connected to an output terminal of the first voltage converting circuit 22. The output terminal of the first voltage converting circuit 22 is further connected to the anode of the diode D. The cathode of the diode D is connected to the power terminal of the processor 20. A control terminal of the processor 20 is connected to a control terminal of the first voltage converting circuit 22 and a control terminal of the second voltage converting circuit 23. An input terminal of the processor 20 is connected to a keyboard 25 and an infrared ray receiving unit 26. An output terminal of the processor 20 is connected to a lamp 29.

An input terminal of the second voltage converting circuit 23 receives the +19V voltage. The second voltage converting circuit 23 converts the +19V voltage to a +12V voltage. An output terminal of the second voltage converting circuit 23 is connected to an input terminal of the first voltage converting circuit 22. The first voltage converting circuit 22 converts the +12V voltage to a +5V voltage and the +3.3V voltage for supplying power to electronic elements 30 and 32. In addition, the output terminal of the second voltage converting circuit 23 is also connected to an electronic element 33 for supplying the +12V voltage to the electronic element 33.

When the motherboard 2 is in a standby state, the first voltage converting circuit 22 and the second voltage converting circuit 23 are idle. The voltage adjusting chip 10 is operational to convert the +19V voltage to the +3.3V voltage for supplying power to the processor 20. The processor 20 monitors whether a control on the keyboard 25 or a remote controller 27 corresponding to the infrared ray receiving unit 26 is activated.

When a preset control is activated, the processor 20 outputs a control signal to initialize the first voltage converting circuit 22 and the second voltage converting circuit 23. The second voltage converting circuit 23 converts the +19V voltage to the +12V voltage and outputs the +12V voltage to the electronic element 33 and the first voltage converting circuit 22. The first voltage converting circuit 22 converts the +12V voltage to the +5V voltage and the +3.3V voltage for supplying power to the electronic elements 32 and 30, and the control circuit 12, powering up the motherboard 2.

The control circuit 12 deactivates the voltage adjusting chip 10 when the control circuit 12 receives the +3.3V voltage, whereby the voltage adjusting chip 10 remains idle when the motherboard 2 is operational. The diode D is turned on to make the first voltage converting circuit 22 outputs the +3.3V voltage to the processor 20. Moreover, the processor 20 lights lamp 29 to indicate that the motherboard 2 is operational. In the embodiment, the diode D is turned off when the first voltage converting circuit 22 is idle, thereby protecting the electronic element 30 when the motherboard 20 is in standby state.

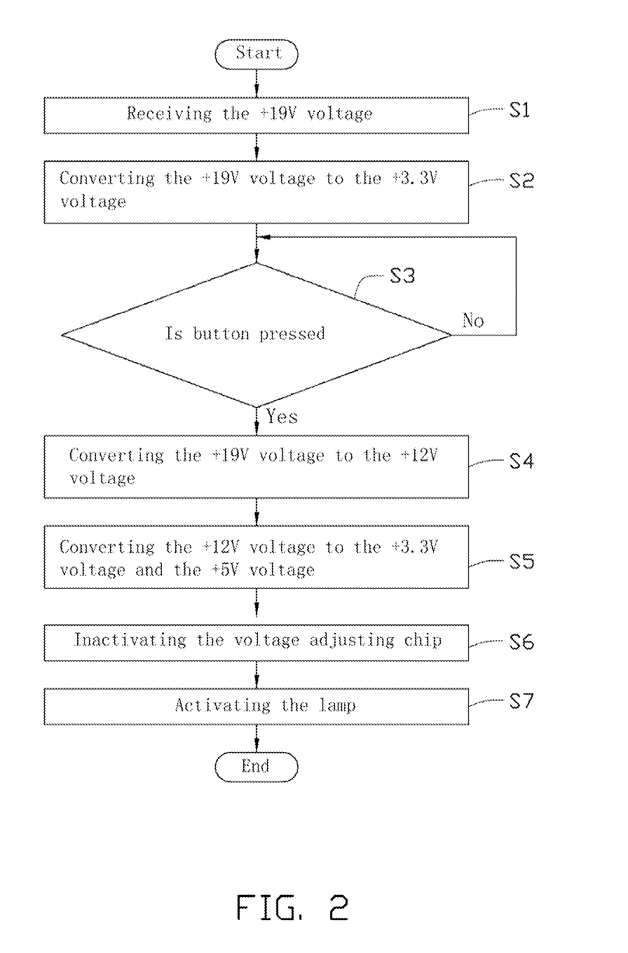

FIG. 2 shows a voltage adjusting method for the motherboard 2, which includes the following steps.

In step S1, the voltage adjusting chip 10 receives the +19V voltage from the motherboard 2.

In step S2, the voltage adjusting chip 10 converts the +19V voltage to the +3.3V voltage for supplying power to the processor 20.

In step S3, the processor 20 determines whether a control on the keyboard 25 or on a remote controller 27 corresponding to the infrared ray receiving unit 26 is activated. If the button on the keyboard 25 or the button on the remote controller 27 corresponding to the infrared ray receiving unit 26 is activated, the process flows to step S4. If no control is activated, step S3 is repeated.

In step S4, the second voltage converting circuit 23 converts the +19V voltage to the +12V voltage, and supplies the +12V voltage to the electronic element 33 and the first voltage converting circuit 22.

In step S5, the first voltage converting circuit 22 converts the +12V voltage to the +3.3V voltage and the +5V voltage. The +3.3V voltage is supplied to the electronic element 30 and the control circuit 12. The +5V voltage is supplied to the electronic element 32.

In step S6, the control circuit 12 deactivates the voltage adjusting chip 10. At this time, the first voltage converting circuit 22 outputs the +3.3V voltage for supplying power to the processor 20.

In step S7, the processor 20 activates the lamp 29.

In the voltage adjusting circuit 1, the first voltage converting circuit 22 supplies power to the processor 20 after the motherboard 2 is at work. Meanwhile, the voltage adjusting chip 10 is idle after the motherboard 2 is at work. As a result, the voltage adjusting circuit 1 avoids the voltage adjusting chip 10 being at work for long time.

The foregoing description of the embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A voltage adjusting circuit for a motherboard, the voltage adjusting circuit comprising:
a voltage adjusting chip to convert a first voltage to a second voltage in response to the motherboard being at a standby state;
a processor to receive the second voltage from the voltage adjusting chip in response to the motherboard being in standby state, and output a control signal in response to the motherboard being activated from the standby state;
a first voltage converting circuit to receive the control signal;
a second voltage converting circuit to receive the control signal, thereby converting the first voltage to a third voltage and outputting the third voltage to the first voltage converting circuit, wherein the first voltage converting circuit converts the third voltage to the second voltage according to the control signal from the processor and supplies the second voltage to the processor; and
a control circuit connected between the first voltage converting circuit and the voltage adjusting chip, wherein the control circuit deactivates the voltage adjusting chip when the control circuit receives the second voltage from the first voltage converting circuit.

2. The voltage adjusting circuit of claim 1, further comprising a diode, wherein an anode of the diode is connected to the first voltage converting circuit, a cathode of the diode is connected to the processor.

3. A motherboard comprising:
a first electronic element;
a voltage adjusting chip to convert a first voltage to a second voltage in response to the motherboard being in a standby state;
a processor to receive the second voltage from the voltage adjusting chip in response to the motherboard being in standby state, and output a control signal in response to the motherboard being activated from the standby state;
a first voltage converting circuit to receive the control signal from the processor;
a second voltage converting circuit to receive the control signal from the processor, thereby to convert the first voltage to a third voltage and output the third voltage to the first voltage converting circuit, wherein the first voltage converting circuit converts the third voltage to the second voltage according to the control signal from the processor and supplies the second power to the processor; and
a control circuit connected between the first voltage converting circuit and the voltage adjusting chip, wherein the control circuit deactivates the voltage adjusting chip when the control circuit receives the second voltage from the first voltage converting circuit.

4. The motherboard of claim 3, further comprising a diode, wherein an anode of the diode is connected to the first voltage converting circuit, a cathode of the diode is connected to the processor.

5. The motherboard of claim 3, further comprising a lamp, wherein when the processor receives the second power from the first voltage converting circuit, the processor lights the lamp.

6. A voltage adjusting method of a motherboard, the motherboard comprising a processor, a voltage adjusting chip, a first voltage converting circuit, a second voltage converting circuit, and a control circuit, the method comprising:
receiving a first voltage by the voltage adjusting chip and the second voltage converting circuit;
converting the first voltage to a second voltage for supplying the second voltage to the processor by the voltage adjusting chip in response to the motherboard being in a standby state;
outputting a control signal by the processor in response to the motherboard being activated from the standby state;
receiving the control signal by the first and second voltage converting circuits from the processor;
converting the first voltage to a third voltage by the second voltage converting circuit;
converting the third voltage to the second voltage for supplying the second voltage to the first electronic element, the control circuit, and the processor;
inactivating the voltage adjusting chip by the control circuit in response to the control circuit receiving the second voltage; and
outputting the second voltage to the processor by the first voltage converting circuit.
